(19) United States
(12) Patent Application Publication
(10) Pub. No.: US 2025/0286009 A1
(43) Pub. Date: Sep. 11, 2025

(54) JOINING STRUCTURE AND JOINING MATERIAL FOR FORMING JOINING PART OF SAID JOINING STRUCTURE

(71) Applicant: Panasonic Intellectual Property Management Co., Ltd., Osaka (JP)

(72) Inventors: AKIO FURUSAWA, Osaka (JP); SHINJI ISHITANI, Hyogo (JP); YUMI TAKAO, Hyogo (JP); HIROHISA HINO, Osaka (JP)

(21) Appl. No.: 19/215,311

(22) Filed: May 21, 2025

Related U.S. Application Data
(63) Continuation of application No. PCT/JP2023/038735, filed on Oct. 26, 2023.

(30) Foreign Application Priority Data
Dec. 6, 2022 (JP) 2022-194829

(51) Int. Cl. H01L 23/00

(52) U.S. Cl. CPC H01L 24/32; H01L 24/29; H01L 2224/29109; H01L 2224/29111; H01L 2224/29113; H01L 2224/29639; H01L 2224/29647; H01L 2224/29655; H01L 2224/32245; H01L 2224/32503; H01L 2924/3512

(57) ABSTRACT

A joining structure including a joining part that joins two objects, in which the joining part includes a first metal phase containing Bi as a main component, the first metal phase having a granular shape with an average size of 0.5 μm to 5 μm, and a second metal phase containing Cu as a main component and containing Sn and In, the first metal phase is dispersed in the second metal phase, and the joining part has a metal composition ratio of Sn: 9.4 mass % to 19.4 mass %, Bi: 26.7 mass % to 36.7 mass %, In: 6.5 mass % to 16.5 mass %, and Cu: a balance.

### TECHNICAL FIELD

The present disclosure relates to a joining structure having heat resistance and containing no lead. The present disclosure more specifically relates to a joining structure of a semiconductor element in which a semiconductor element formed of a material such as Si, GaN, or SiC is joined to a lead frame. The present disclosure also relates to a joining material for forming a joining part of the joining structure.

### BACKGROUND ART

Semiconductor electronic components are mounted on a circuit board using a solder material as a joining material. When a semiconductor element such as a Si chip is joined to a base plate, Au-20 mass % Sn having a melting point of 280° C. is typically used as a joining material. FIG. 8 is a sectional view schematically illustrating semiconductor element 1 mounted on base plate 2.

In the present specification, the expression “A-x mass % B (A and B are metal elements, and x is a percentage value)” is used to describe the composition of an alloy. This expression means that the alloy is made of the metal elements A and B, in which the metal element B is contained in an amount of x mass %, and the balance is mass %(=100−x) of the metal element A.

First, external electrode 4 of semiconductor element 1 is soldered to a lead frame including insulating substrate 6 and insulating circuit board electrode 5 using, for example, a solder material having a melting point of 280° C. (for example, Au-20 mass % Sn) with a heat tool type chip bonder device to form first joining part 3. Next, in a hot air circulation reflow device, insulating substrate 6 is soldered to base plate 2 using, for example, a solder material having a melting point of 220° C. (for example, Sn-3 mass % Ag-0.5 mass % Cu) to form second joining part 7.

When insulating substrate 6 to which semiconductor element 1 is joined is soldered to base plate 2, insulating substrate 6 is put into the reflow device heated to a temperature higher by, for example, 20° C. to 40° C. than the melting point of the solder material forming second joining part 7. In such a case, the temperature of the solder material of first joining part 3 may reach a high temperature of 240° C. to 260° C., and the solder material of first joining part 3 may melt. Semiconductor element 1 is joined to insulating substrate 6 while being controlled to be horizontal with respect to the insulating substrate. However, under such a high temperature condition, when the solder material of first joining part 3 melts, semiconductor element 1 may incline. In such a case, there is a possibility that circuit breakdown occurs because of local heat generation of semiconductor element 1, or electrical characteristics of semiconductor element 1 change, and a defect occurs in a final product.

Thus, the solder material of first joining part 3 used for joining semiconductor element 1 is required to have resistance to a temperature higher than the maximum temperature that the reflow device reaches at the time of soldering, for example, a heat-resistant temperature of more than or equal to 260° C.

In addition, in recent years, GaN chips capable of operating at a higher speed than Si chips and SiC chips capable of higher-output operation than Si chips have been increasingly used. Since the GaN chip or the SiC chip has a larger amount of heat generation during operation than the Si chip, when stress derived from a difference in linear expansion coefficient between such a semiconductor element and the insulating substrate is applied to the joining part, a crack failure may occur in which the joining part cannot withstand distortion and breaks. Conventionally, an aluminum cooling fin or the like is attached to base plate 2 to release heat. However, when the amount of heat generation increases, first joining part 3 having a small heat flux sectional area limits the rate of heat release, and thus it is becoming difficult to sufficiently release heat. In this sense as well, it is necessary to improve the heat resistance of first joining part 3.

Thus, as a first joining material having improved heat resistance, an Ag nanopaste in which Ag nanoparticles and a binder are mixed has been proposed (for example, see PTL 1 described below). As the silver nanoparticles constituting the joining material, particles having an average particle size of less than or equal to 200 nm are used, and by using silver nanoparticles having such an average particle size, a joining structure having high joining strength can be formed.

In addition, a second joining material containing a plurality of Ag powders having different average particle sizes has also been proposed (for example, see PTL 2 described below). The joining material includes a mixture of three types of particles (Ag particles having an average particle size of less than 10 nm, Ag particles having an average particle size of 15 nm to 45 nm, and Ag particles having an average particle size of 100 nm to 300 nm). Using such mixed particles makes it possible to obtain a joining structure having high joining strength even under no pressure or under self-pressure.

Further, a third joining material using a transition liquid phase sintering technique has been proposed (for example, see PTL 3 described below). The joining material includes first metal particles having a melting point of less than or equal to 200° C. and second metal particles that forms an intermetallic compound with the first metal particles. Using such mixed particles makes it possible to obtain a joining structure in which a second metal phase is dispersed in a first metal phase having a high melting point.

### CITATION LIST

### Patent Literatures

PTL 1: Japanese Patent No. 5986929

PTL 2: Japanese Patent No. 5620122

PTL 3: Unexamined Japanese Patent Publication No. 2020-176331

### SUMMARY OF THE INVENTION

A joining structure according to one aspect of the present disclosure is a joining structure including a joining part that joins two objects, in which the joining part includes a first metal phase containing Bi as a main component, the first metal phase having a granular shape with an average size of 0.5 μm to 5 μm, and a second metal phase containing Cu as a main component and containing Sn and In, the first metal phase is dispersed in the second metal phase, and the joining part has a metal composition proportion of Sn: 9.4 mass % to 19.4 mass %, Bi: 26.7 mass % to 36.7 mass %, In: 6.5 mass % to 16.5 mass %, and Cu: a balance.

A joining material according to one aspect of the present disclosure is a joining material for forming a joining part that joins two objects, the joining material including a composite metal particle including a first metal particle as a core and a second metal particle covering a surface of the core, the first metal particle containing a first metal containing a Sn—Bi—In-based alloy as a main component, the second metal particle containing a second metal made of a simple metal of Cu, Ag, or Ni that reacts with Sn or In to generate an intermetallic compound or an alloy between these simple metals, a first metal particle that is present separately from the composite metal particle, the first metal particle containing a first metal containing a Sn—Bi—In-based alloy as a main component, and a binder covering a whole, in which the whole has a metal composition proportion of Sn: 9.4 mass % to 19.4 mass %, Bi: 26.7 mass % to 36.7 mass %, In: 6.5 mass % to 16.5 mass %, and the second metal: a balance.

### BRIEF DESCRIPTION OF THE DRAWINGS

FIG. 1 is a schematic sectional view schematically illustrating a sectional structure of one aspect of a joining structure according to a first exemplary embodiment.

FIG. 2 is a schematic view schematically illustrating an example of a process of producing a joining material used to obtain the joining structure according to the first exemplary embodiment.

FIG. 3 conceptually illustrates a sectional structure of a joining material in a process of forming the joining structure according to the first exemplary embodiment. Part (a) of FIG. 3 is a schematic sectional view illustrating the sectional structure of the joining material before the joining material is heated by soldering, part (b) of FIG. 3 is a schematic sectional view illustrating the sectional structure in a state where an intermetallic compound is being formed in a liquid phase generated by melting of a second metal particle, and part (c) of FIG. 3 is a schematic sectional view illustrating the sectional structure of the joining structure after joining is performed by soldering.

FIG. 4 is a graph showing a relationship between the Bi content in a joining part and the melting temperature and joining strength of the joining part.

FIG. 5 is a graph showing a relationship between the median size of a first metal phase of the joining part and the melting temperature and the joining strength of the joining part.

FIG. 6 is Table 1 showing the results of melting temperatures and joining strengths of various joining parts having different Bi contents contained in the joining parts.

FIG. 7 is Table 2 showing the results of melting temperatures and joining strengths of various joining parts having different median sizes of the first metal phase.

FIG. 8 is a schematic sectional view schematically illustrating a sectional structure in a state where a semiconductor element is joined to a base plate.

### DESCRIPTION OF EMBODIMENT

The above-described first joining material needs to be heated to a high temperature of 150° C. to 500° C., and the temperature needs to be maintained for a long time of 30 minutes to 60 minutes to form the joining structure. In addition, it is necessary to raise the temperature while pressurizing the object to be joined against the substrate, and the pressure is 20 MPa at maximum. Thus, the object to be joined may break.

The above-described second joining material has a configuration in which Ag nanoparticles having different average particle sizes are mixed, and it can form a joining structure under no pressure or under self-pressure, but the temperature needs to be maintained at a high temperature of 350° C. for 5 minutes. When the joining temperature is 200° C., the holding time is as long as 30 minutes.

The above-described third joining material can form a joining structure with heating at 200° C. for 10 minutes, and it can maintain a heat-resistant temperature of more than or equal to 260° C. when joining is performed by heating at 200° C. using metal particles having a melting point of 150° C. However, when metal particles having a melting point of 100° C. are used, and joining is performed by heating at 150° C., a component that melts at about 100° C. precipitates. Thus, the heat-resistant temperature greatly decreases, and heat resistance cannot be maintained.

An object of the present disclosure is to provide a joining structure having a heat-resistant temperature of more than or equal to 260° C. and capable of forming at a relatively low heating temperature and a short holding time to solve the problem that the heat-resistant temperature is lowered when joining is performed by heating at 150° C.

A joining structure according to a first aspect is a joining structure including a joining part that joins two objects, in which the joining part includes a first metal phase containing Bi as a main component, the first metal phase having a granular shape with an average size of 0.5 μm to 5 μm, and a second metal phase containing Cu as a main component and containing Sn and In, the first metal phase is dispersed in the second metal phase, and the joining part has a metal composition proportion of Sn: 9.4 mass % to 19.4 mass %, Bi: 26.7 mass % to 36.7 mass %, In: 6.5 mass % to 16.5 mass %, and Cu: a balance.

In a joining structure according to a second aspect, in the first aspect, the second metal phase may contain Cu₃(Sn, In).

In a joining structure according to a third aspect, in the first or second aspect, at least one of the two objects may be Cu, and at least one of Cu₆Sn₅ and Cu₃Sn may be contained between the at least one of the two objects and the second metal phase.

A joining material according to a fourth aspect is a joining material for forming a joining part that joins two objects, the joining material including a composite metal particle including a first metal particle as a core and a second metal particle covering a surface of the core, the first metal particle containing a first metal containing a Sn—Bi—In-based alloy as a main component, the second metal particle containing a second metal made of a simple metal of Cu, Ag, or Ni that reacts with Sn or In to generate an intermetallic compound or an alloy between these simple metals, a first metal particle that is present separately from the composite metal particle, the first metal particle containing a first metal containing a Sn—Bi—In-based alloy as a main component, and a binder covering a whole, in which the whole has a metal composition proportion of Sn: 9.4 mass % to 19.4 mass %, Bi: 26.7 mass % to 36.7 mass %, In: 6.5 mass % to 16.5 mass %, and the second metal: a balance.

According to the joining structure according to one aspect of the present disclosure, the intermetallic compound as the second metal phase forms a three-dimensional network structure, and thus the first metal phase is held in the network structure. As a result, even when the joining part is disposed under a high-temperature environment in which the first metal particles melt, the melted first metal phase is still held by the network structure of the second metal phase, and the structure of the joining part as a whole is substantially not affected by such a high temperature.

Hereinafter, a joining structure and a joining material according to the present exemplary embodiment will be described in more detail with reference to the accompanying drawings. The following description is an illustration of specific forms for carrying out the present disclosure, and the present disclosure is not limited to such forms.

### First Exemplary Embodiment

### Joining Structure

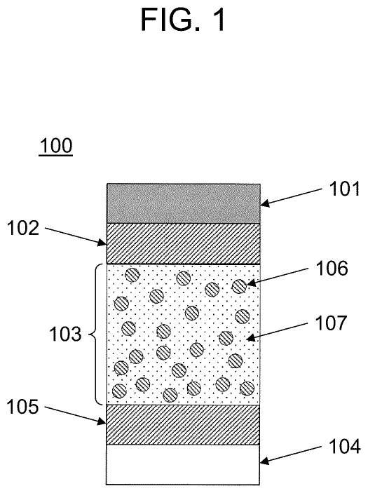

FIG. 1 schematically illustrates joining structure 100 according to a first exemplary embodiment. FIG. 1 is a schematic sectional view schematically illustrating a sectional structure of one aspect of joining structure 100 according to the first exemplary embodiment. Joining structure 100 includes joining part 103 that joins two objects. One object is external electrode 102 of semiconductor element 101. The other object is electrode 105 of insulating substrate 104. Illustrated joining part 103 is formed using a joining material containing, for example, first metal particles containing a Sn—Bi—In-based alloy as a first metal and second metal particles containing, for example, Cu as a second metal.

### Joining Part

Joining part 103 includes first metal phase 106 containing Bi derived from the first metal particles as a main component and second metal phase 107 derived from CuSnIn that is an intermetallic compound derived from the first metal particles and the second metal particles and containing CuSnIn as a main component. As illustrated in the drawings, first metal phase 106 is surrounded by second metal phase 107. In other words, first metal phase 106 is dispersed in second metal phase 107 that is a parent phase. The first metal phase corresponds to the first metal particles, but it is smaller than the original first metal particles because an intermetallic compound is generated from the liquid phase in which the first metal has melted. When insulating circuit board electrode 105 or/and external electrode 102, which are objects to be joined, are Cu, an intermetallic compound layer of Cu₆Sn₅ or/and Cu₃Sn is formed between insulating circuit board electrode 105 or/and external electrode 102 and joining part 103.

Second metal phase 107 has a three-dimensional network structure, includes first metal phase 106 therein as illustrated, and joins external electrode 102 and insulating circuit board electrode 105. Such a parent phase part has a melting point corresponding to the melting point of the intermetallic compound to be formed, for example, a melting point of more than or equal to 400° C. As a result, even when the joining part is heated to more than or equal to 300° C., for example, a high temperature close to 400° C., the network structure of the parent phase part is maintained without melting. Thus, joining part 103 does not break but has excellent heat resistance.

### Object

The object to be joined by the joining structure according to the first exemplary embodiment is an object to be electrically and physically joined, that is, an object to be mechanically bonded while electrical conduction is ensured. The object may be any appropriate electronic component, electric component, or the like. Specifically, examples of the object include electrodes of a semiconductor element, a circuit board, a lead frame, and an insulating circuit board, and electrodes of various other electric and electronic components. A semiconductor element will be described as an example of such an object to be joined.

### Semiconductor Element

The semiconductor element may be made of any appropriate material, and a semiconductor element obtained by cutting a wafer having a size of, for example, 6 inches and a thickness of, for example, 0.3 mm into a size of, for example, 2 mm×1.6 mm is used. The semiconductor element may be made of GaN, Si, SiC, or the like, or may be made of GaAs, InP, ZnS, ZnSe, SiGe, or the like. The semiconductor element may have any appropriate dimensions, and a semiconductor element having large dimensions of 6 mm×5 mm, 4.5 mm×3.55 mm, or a semiconductor element having small dimensions of 3 mm×2.5 mm may be used depending on the function. The semiconductor element may have any appropriate thickness, and may have a thickness of 0.4 mm, 0.3 mm, 0.2 mm, 0.15 mm, or the like depending on the dimensions of the semiconductor element.

### Insulating Substrate

The insulating substrate is typically made of ceramics, and to secure the joinability to the joining material, for example, a film of Au having a thickness of 0.3 μm is formed as a surface-treated layer on the joining material side of the insulating substrate by an electrolytic plating method. For the surface-treated layer, Ag, Cu, Ni, Pt, Pd, Sn, or the like, which is a metal having good joinability to the joining material, may be used. The thickness is more than or equal to 0.1 μm in consideration of variation in film formation thickness. The film formation method is not limited to the electrolytic plating method, and a vapor deposition method, an electroless plating method, or the like may be used.

Thus, the joining structure according to the first exemplary embodiment includes a joining part between the semiconductor element and the insulating substrate as objects, and the joining part includes first metal phase 106 and second metal phase 107 described above.

### Joining Material

The joining material according to the first exemplary embodiment is a joining material for forming a joining part that joins two objects, and the joining material includes a composite metal particle, a first metal particle, and a binder covering the whole. The composite metal particle includes the first metal particle as a core and a second metal particle covering a surface of the first metal particle. The first metal particle contains a first metal containing a Sn—Bi—In-based alloy as a main component. The second metal particle is made of a simple metal of Cu, Ag, or Ni capable of reacting with Sn or In to generate an intermetallic compound, or an alloy between these simple metals. The first metal particle contains a first metal that is present separately from the composite metal particle, the first metal containing a Sn—Bi—In-based alloy as a main component. The metal composition ratio of the entire joining material is Sn: 9.4 mass % to 19.4 mass %, Bi: 26.7 mass % to 36.7 mass %, In: 6.5 mass % to 16.5 mass %, and the second metal: the balance.

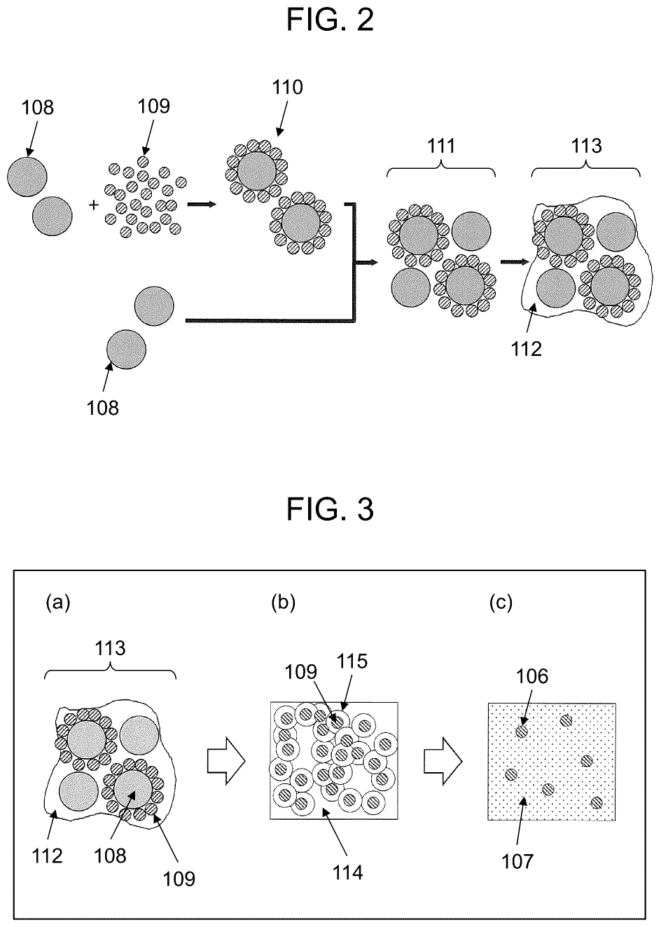

FIG. 2 schematically illustrates an example of a process of producing a joining material used to obtain the joining structure according to the first exemplary embodiment. Hereinafter, the process of producing the joining material will be described.
(1) First, first metal particles 108 and second metal particles 109 are mixed at a predetermined ratio (that is, the mixing ratio) to prepare composite metal particles 110.
(2) Next, composite metal particles 110 and first metal particles 108 to be newly added are mixed at a predetermined ratio to prepare particle mixture 111.
(3) Next, binder 112 (a typically used compound such as diethylene glycol monohexyl ether or 2-ethyl-1,3-hexanediol as a solvent, and 1,3-diphenylguanidine hydrobromide or stearic acid as a reducing agent, for example) is added, and these are stirred and mixed to obtain joining material 113.

In addition to the first metal particles, the second metal particles, and the binder, joining material 113 may further contain other components as necessary. For example, a castor oil, GELOL MD, or the like may be contained to impart thixotropy. Rosin, polybutene, or the like may be contained to adjust the viscosity. The first metal contained in first metal particles 108 is, for example, Sn-55 mass % Bi-20 mass % In (melting point: 100° C.), and the median particle size of the first metal particles is, for example, 6 μm.

The second metal contained in second metal particles 109 is, for example, Cu (melting point: 1085° C.), and the median particle size of the second metal particles is, for example, 200 nm on average. These metal particles may contain, in addition to the metal contained therein, other components as necessary, and may contain other components that are inevitably contained in the production of the particles. In any case, other components may be included as long as an unacceptable adverse effect on the object of the present disclosure does not occur. Usually, the first metal particles are made of the first metal, and the second metal particles are made of the second metal. The mass ratio of first metal particles 108 to the total mass of first metal particles 108 and second metal particles 109, that is, the mass ratio of first metal particles 108 to the mass of particle mixture 111, that is, the mixing ratio, is 50 mass %, for example. The mixing ratio is not limited to 50 mass %, and the ratio can be appropriately adjusted in the range from 40 mass % to 63 mass %. The amount of the binder contained in the joining material may be such that handling of the joining material, for example, supply of the joining material to the electrode with a dispenser is not disturbed. The amount of the binder is usually 9 wt % to 30 wt % on a mass basis with respect to the total amount of the binder and the particle mixture, and it may be, for example, about 20 wt %.

### Joining Method (Method for Producing Joining Structure)

FIG. 3 schematically illustrates a process of forming joining structure 100 according to the first exemplary embodiment by forming a joining part between two objects using a joining material. Joining material 113 prepared as described above is supplied onto an insulating circuit board electrode (not illustrated) as one object with a dispenser, a semiconductor element (not illustrated) as the other object is mounted on joining material 113, and then these are heated to a predetermined temperature to form a joining part. In FIG. 3, the two objects are not illustrated, and a state in which the state of joining material 113 between the two objects changes to form a joining part is illustrated.
(A) Part (a) of FIG. 3 schematically illustrates a state of joining material 113 before the joining material is heated and soldered after the semiconductor element as the other object is mounted. A particle mixture (first metal particles 108+second metal particles 109) is present in binder 112. In a state where the semiconductor element is mounted as described above, soldering is performed by heating to a temperature higher than the melting point of the first metal particles (for example, a temperature higher by 20° C. than the melting point of the first metal particles), for example, 150° C. in a nitrogen atmosphere with an oxygen concentration of 200 ppm, for example.
(B) In the process of heating in this manner, as illustrated in part (b) of FIG. 3, binder 112 evaporates, the first metal particles are melted and substantially integrated to form a liquid phase, and second metal particles 109 that are not melted are dispersed. As illustrated, in a state where first metal particles 114 that have melted surround second metal particles 109, the first metal melts from first metal particles 108, and Sn and In of melted first metal particles 114 react with Cu of the second metal particles to form intermetallic compound 115. As a result, as illustrated, intermetallic compound 115 is formed around second metal particles 109.
(C) The formation amount of the intermetallic compound increases with the lapse of the heating holding time, and the region of the intermetallic compound expands as illustrated in part (c) of FIG. 3. A network structure is formed after it is held for approximately 10 minutes, and a joining part is formed when the network structure is then cooled to room temperature.

In this joining part, first metal phase 106 derived from the first metal particles and remaining without being involved in the formation of the intermetallic compound is present in the network structure of second metal phase 107 made of the intermetallic compound.

Joining material 113 capable of forming a joining part as described above is prepared by mixing first metal particles 108 having a melting point of less than or equal to 150° C. (for example, first metal particles made of a first metal of Sn-55 mass % Bi-20 mass % In, melting point: 100° C.) and second metal particles having a melting point higher than the melting point of the intermetallic compound to be formed (having a melting point higher than the melting point of the first metal particles) (for example, second metal particles made of Cu as second metal, melting point: 1085° C.). Thus, first metal particles 108 are melted only by heating this joining material to, for example, 150° C., Cu dissolves in Sn-55 mass % Bi-20 mass % In that has melted in a short time and diffuses therein to form an intermetallic compound with Sn and In in the liquid phase. Therefore, the joining part can be formed in a short time.

Thus, the method for forming a joining part or a joining method includes: a step of supplying a joining material to one of two objects to be joined; a step of placing the other object on the joining material that has been supplied and disposing the joining material between the two objects; a step of heating the joining material and the objects to a temperature higher than the melting point of the first metal particle, preferably, by 20° C., for example, heating to 150° C.; and a step of holding the heating state for a predetermined time (for example, 1 minute to 30 minutes, preferably 10 minutes or more), and then cooling.

In forming the joining structure described above, when the joining material is heated until the first metal particles melt, the second metal particles diffuse and react in the liquid phase to be generated, and an intermetallic compound is generated between Sn and In of the first metal particles. Thereafter, cooling is performed and then a joining part is formed. As illustrated and described in FIG. 1, in this joining part, the generated intermetallic compound forms a three-dimensional network structure (or a matrix structure) and constitutes second metal phase 107. The three-dimensional network structure contains first metal phase 106 derived from the first metal particles (the first metal particles remain without being involved in the formation of the intermetallic compound).

That is, the intermetallic compound as second metal phase 107 forms a three-dimensional network structure, whereby first metal phase 106 can be held in the network structure. As a result, even when the joining part is disposed under a high-temperature environment such as a temperature at which the first metal particles melt or higher (however, the temperature is lower than the melting point of the intermetallic compound), for example, 300° C., the intermetallic compound can maintain the network structure without melting. As a result, even when first metal phase 106 melts, it is still held by the network structure of second metal phase 107, and the structure of the joining part as a whole is substantially not affected by such a high temperature.

In addition, by changing the configurations of the first metal particles and the second metal particles of the joining material that can form the network structure of the intermetallic compound, the heat-resistant temperature and the joining strength of the joining part can be controlled. Specifically, by appropriately selecting the mixing ratio of the first metal particles and the second metal particles and the median size of the first metal particles to adjust the median size of the first metal phase, it is possible to achieve a desirable melting point of the joining part (corresponding to the heat resistance of the joining part) and joining strength.

As a result, even when the joining structure according to the first exemplary embodiment is used for joining a semiconductor element having a large amount of heat generation, such as a GaN semiconductor element or a SiC semiconductor element, cracks are less likely to occur at the joining part, and a decrease in reliability of the joining structure is suppressed. In addition, in the case of soldering with a heating device in forming the joining structure according to the first exemplary embodiment, since the first metal particles melt at a temperature of less than or equal to 150° C., soldering can be performed at a relatively low temperature for a short time, and energy consumption in an assembly process of joining the semiconductor element can be reduced.

### First Metal Particles

In the joining material according to the first exemplary embodiment, the first metal particles have a granular form containing the first metal, and are usually made of the first metal. The granular form is a so-called “granular” form including a spherical shape, a substantially spherical shape, an elliptical spherical shape, a polyhedral shape, a core-shell shape, and a shape of a combination of at least two of these shapes. The first metal particles constituting the joining material have a melting point of less than or equal to 150° C., and are made of the first metal. When the joining material is heated to form a joining part, the first metal particles melt at a temperature of less than or equal to 150° C. to form a liquid phase in which the first metal of the first metal particles is melted.

The first metal is an alloy of a Sn—Bi—In-based alloy and another metal, and another metal is at least one selected from Ag, Cu, and Ni. Specific examples of the allow include a Sn—Bi—In-based alloy, a Sn—Bi—In—Ag-based alloy, and a Sn—Bi—In—Cu-based alloy. The alloy may be a three-component alloy or a multicomponent alloy composed of more components, and it may be, for example, a Sn—Bi—In—Ag—Cu alloy. More specifically, Sn-55 mass % Bi-20 mass % In (melting point: 100° C.), Sn-50 mass % Bi-25 mass % In (melting point: 106° C.), and the like can be exemplified as the first metal. That is, Bi may be in the range from 50 mass % to 55 mass %, and In may be in the range from 20 mass % to 25 mass %. In this case, the balance is Sn, but the balance may include metal or the like inevitably contained. The second metal may be one type of alloy or a plurality of types of alloys.

### Second Metal Particle

In the joining material according to the first exemplary embodiment, second metal particles 109 have a granular form containing the second metal, and are usually made of the second metal. Like the first metal particles, the granular form is a so-called “granular” form including a spherical shape, a substantially spherical shape, an elliptical spherical shape, a polyhedral shape, a core-shell shape, and a shape of a combination of at least two of these shapes.

Examples of the second metal constituting the second metal particles include a metal or an alloy made of a metal element capable of forming an intermetallic compound with Sn, In, or the like constituting the first metal by dissolving in a liquid phase generated by melting of the first metal particles and diffusing therein. Specifically, examples of the second metal include elemental metals of Cu, Ag, and Ni, and alloys of these elemental metals and at least one other metal, for example, alloys such as Cu—Ag-based alloys, Ag—Cu-based alloys, and Cu—Ni-based alloys. At least one metal element of these metals and alloys forms an intermetallic compound with Sn, In, or the like. Among them, Cu or an alloy thereof is particularly preferable as the second metal. The second metal may be one metal or alloy, may be a plurality of metals, may be a plurality of alloys, or may be a combination of one or a plurality of metals and one or a plurality of alloys.

At least one (for example, Cu) of metal elements constituting such a second metal dissolves and diffuses in a liquid phase generated by melting of the first metal particles and reacts with Sn, In, or the like derived from the first metal of the first metal particles present in the liquid phase to generate at least one intermetallic compound. For example, Cu as the second metal reacts with Sn, In, or the like in the liquid phase of the melted first metal particles to form a Cu—Sn-based intermetallic compound (for example, Cu₃(Sn, In), Cu₆(Sn, In)₅, Cu₃Sn, Cu₆Sn₅, or the like). It is known that Sn forms various intermetallic compounds with various metals. The intermetallic compound is not limited to Cu—Sn-based intermetallic compounds, but various intermetallic compounds such as Sn—Ni-based intermetallic compounds, Sn—Ag-based intermetallic compounds, Sn—Ag—Cu-based intermetallic compounds, and Sn—Cu—Ni-based intermetallic compounds are known.

The melting point of the second metal particles is higher than the intended heat-resistant temperature, preferably at least higher than the intended heat-resistant temperature by 200° C., and more preferably at least higher by 300° C. The intermetallic compound formed in the joining structure of the present disclosure has a melting point between the melting point of the first metal particles and the melting point of the second metal particles. Since the intermetallic compound melts at its melting point, the melting point of the intermetallic compound substantially corresponds to the heat-resistant temperature of the joining part. Thus, to increase the heat-resistant temperature, it is preferable to increase the melting point of the intermetallic compound to be formed. The melting point of the intermetallic compound typically increases when the melting point of the second metal is increased.

Regarding the first metal particles such as Cu particles, when the median particle size of the second metal particles is less than 20 nm, it is not easy to uniformly mix the first metal particles with the second metal particles, and in consideration of this, the median particle size of the second metal particles is preferably more than or equal to 20 nm.

### Bi Content Ratio of Joining Part

The joining structure according to the first exemplary embodiment includes the first metal phase and the second metal phase. The ratio between the second metal phase forming the three-dimensional network structure and the first metal phase dispersed inside the second metal phase is an important factor for the performance of the joining part to be formed. The first metal phase is Bi of the first metal that is derived from the first metal particles and remains without being involved in the formation of the intermetallic compound. Thus, the ratio between the first metal phase and the second metal phase can be quantified by measuring the Bi content.

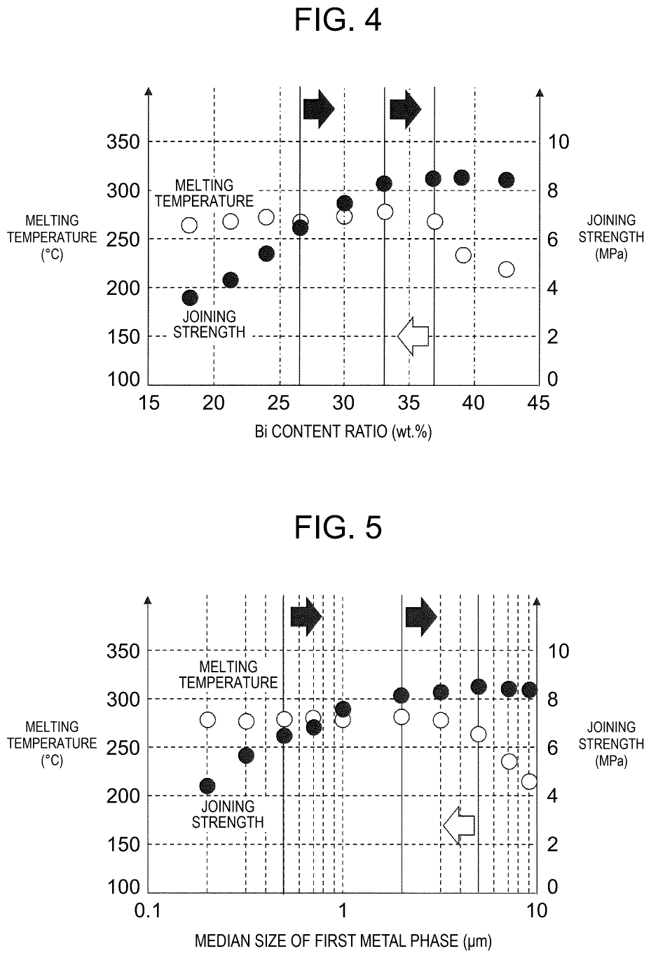

FIG. 4 illustrates the results of preparing paste-like joining materials in which the ratio (on a mass basis) of the amount of the first metal particles to the total amount of the first metal particles and the second metal particles, that is, the Bi content ratio of the joining part is variously changed, and measuring the melting temperature and the joining strength of the joining parts formed using the paste-like joining materials. Particles formed of a first metal (Sn-55 mass %-20 mass % In) having a median particle size of 6 μm were used as the first metal particles, and Cu particles having a median particle size of 200 nm were used as the second metal particles. A particle mixture in which the first metal particles and the second metal particles were mixed was mixed with a binder (diethylene glycol monohexyl ether and 1,3-diphenylguanidine hydrobromide) to obtain a paste of a joining material. Thereafter, the paste of the joining material was transferred onto a Cu plate (20 mm×10 mm) with a thickness of 100 μm, a Si chip (1 mm×1 mm) was placed thereon, and the joining material was heated at 200° C. for 10 minutes and then cooled to room temperature to obtain a joining structure.

In FIG. 4, the horizontal axis represents the Bi content ratio of the joining part, and the vertical axis represents the melting temperature (white circle mark ○ in FIG. 4) measured with a differential scanning calorimeter (DSC) and the joining strength (black circle mark ● in FIG. 4) of the Si chip of 1 mm×1 mm measured with a bond tester. The melting temperature of the joining part was measured for a test piece cut out from the formed joining part using a differential scanning calorimeter. Specifically, among the absorption peaks obtained at the time of temperature rise with DSC, the temperature of the first absorption peak bottom positioned at a temperature higher than the melting point of the first metal was defined as the melting temperature of the joining part.

As can be understood from FIG. 4, when the Bi content ratio is less than 26.7 mass %, the joining strength decreases to less than 6 MPa. This is because when the Bi content has decreased, that is, when the ratio of the amount of the first metal particles to the total amount of the joining material has decreased, the amount of the liquid phase derived from melting of the first metal particles, which is necessary for forming the intermetallic compound, becomes insufficient. It is considered that, as a result, the amount of diffusion of the second metal particles into the liquid phase decreases, and the generation of the intermetallic compound does not sufficiently proceed. Thus, the Cu particles derived from the second metal particles remain in the second metal phase present in the joining part, and voids are generated between the Cu particles.

In a particularly preferable aspect, the Bi content ratio is more preferably more than or equal to 33 mass % from the viewpoint that the joining strength is particularly desirably more than or equal to 8 MPa. When the Bi content ratio is increased to more than 36.7 mass %, the melting temperature decreases to less than 260° C. This is considered to be because the amount of the second metal particles is reduced and the generation of the intermetallic compound does not sufficiently proceed, and thus the remaining amount of Sn—In as the first metal in the first metal phase present in the joining part increases.

In consideration of these, in a preferred embodiment, when the Bi content ratio of the joining part is more than or equal to 26.7 mass %, the joining strength is more than or equal to 6 MPa, and in a more preferred embodiment, when the Bi content ratio is more than or equal to 33 mass %, the joining strength is more than or equal to 8 MPa. Thus, in a preferred embodiment of the present disclosure, the Bi content of the joining part is 26.7 mass % to 36.7 mass %, and in a more preferred embodiment, the Bi content is 33 mass % to 36.7 mass %. When the Bi content ratio of the joining part has a value in this range, a joining structure including a joining part having sufficient joining strength and a melting temperature of more than or equal to 400° C. is obtained.

### Median Size of First Metal Phase

In the present specification, the median size referred to with respect to the first metal phase was measured using typically used image analysis software (for example, WinROOF) on an image obtained by observing a section of the joining part with an electron microscope.

FIG. 5 illustrates the results of preparing paste-like joining materials in which the median size of first metal particles 108 contained in the joining material is variously changed, and measuring the melting temperature and the joining strength of the joining parts formed using the paste-like joining materials. The first metal phase is mainly composed of Bi of the first metal that is derived from the first metal particles and remains without being involved in the formation of the intermetallic compound. Thus, the median size of the first metal phase can be changed by variously changing the median size of the first metal particles.

As the first metal particles, a plurality of particles formed of a first metal of Sn-55 mass % Bi-20 mass % In and having a median particle size changed in the range from 0.8 μm to 15 μm were used. The mass ratio of the first metal particles to the total mass of the first metal particles and the second metal particles was fixed at 50 mass %. A particle mixture in which the first metal particles and the second metal particles were mixed was mixed with a binder (diethylene glycol monohexyl ether and 1,3-diphenylguanidine hydrobromide) to obtain a paste of a joining material. Thereafter, a paste of the joining material was transferred onto a Cu plate (20 mm×10 mm) with a thickness of 100 μm, a Si chip (1 mm×1 mm) was placed thereon, and the joining material was heated at 200° C. for 10 minutes and then cooled to room temperature, whereby a joining structure formed with a joining part was obtained. The melting temperature and the joining strength of the joining part were measured in the same manner as described above.

As can be understood from FIG. 5, when the median particle size of the first metal phase is less than 0.5 μm, the joining strength decreases to less than or equal to 6 MPa. This is considered to be because the melting becomes insufficient as the specific surface area of the first metal particles increases, and as a result, the liquid phase derived from the melting of the first metal particles necessary for the generation of the intermetallic compound decreases, and the production of the intermetallic compound is suppressed.

In a particularly preferable aspect, the median size of the first metal phase is more preferably more than or equal to 2 μm from the viewpoint that the joining strength is particularly desirably more than or equal to 8 MPa. When the median particle size of the first metal phase is increased to more than 3 μm, the melting temperature decreases to less than 270° C., and when the median particle size of the first metal phase is increased to more than 5 μm, the melting temperature decreases to less than 260° C. This is considered to be because the generation of the intermetallic compound becomes insufficient as the specific surface area of the first metal particles decreases, Sn, Bi, and the like remaining without being involved in the generation of the intermetallic compound in the first metal phase present in the joining part increase, and thus a low melting point phase is generated.

In consideration of these, in a preferred embodiment, when the median size of the first metal phase is more than or equal to 0.5 μm, the joining strength is more than or equal to 6 MPa, and in a more preferred embodiment, when the median size is more than or equal to 2 μm, the joining strength is more than or equal to 8 MPa. Thus, in a preferred aspect of the present disclosure, the median size of the first metal phase is 0.5 μm to 5 μm, and in a more preferred aspect, the median size is 2 μm to 5 μm. By using a joining part having the median size of the first metal phase within this range, a joining structure including a joining part having sufficient joining strength and a joining part with a melting temperature of more than or equal to 400° C. is obtained. In the present specification, the “average size” means a median size.

### EXAMPLES AND COMPARATIVE EXAMPLES

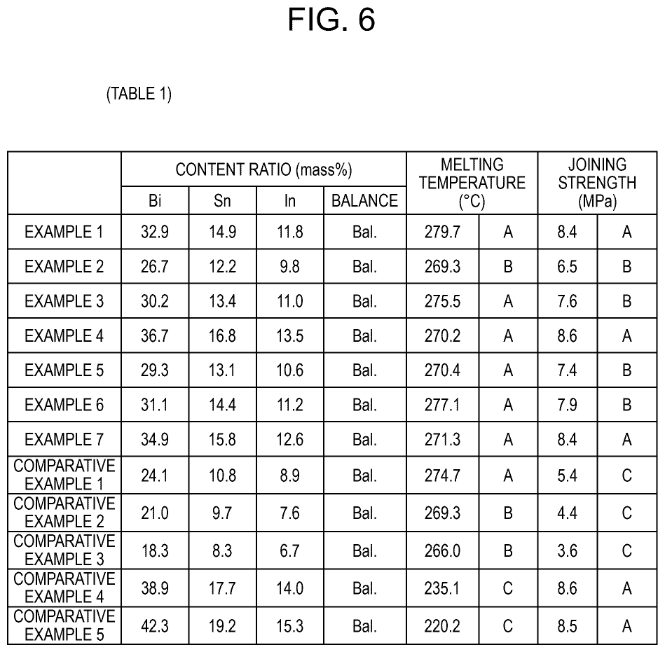

In the joining part of the joining structure, it is necessary to achieve both the melting temperature and the joining strength. To examine this compatibility, an experiment was conducted in which joining parts in which the Bi content ratio of the joining part was variously changed was formed in the same manner as described above, and the melting temperature and the joining strength thereof were measured. The results are shown in Table 1 of FIG. 6.

In the column of melting temperature in Table 1, the standard of the predetermined heat-resistant temperature of the joining part is set to 260° C. “B” means a good evaluation with respect to the standard, “A” means a sufficiently good evaluation with a temperature of more than or equal to 270° C., and “C” means an evaluation with a temperature of less than 260° C., not satisfying the predetermined heat-resistant temperature. In the column of joining strength in Table 1, the standard of the predetermined joining strength of the joining part is set to 6 MPa. “B” means a good evaluation with respect to the standard, “A” means a sufficiently good evaluation with a joining strength of more than or equal to 8 MPa, and “C” means an evaluation with a joining strength of less than 6 MPa, not satisfying the predetermined joining strength. An experimental example in which both the melting temperature and the joining strength were evaluated as “B” or “A” was defined as “Example”, and an experimental example in which either evaluation was evaluated as “C” was defined as “Comparative Example”.

### Example 1

A joining material prepared using the first metal particles and the second metal particles was transferred onto a Cu plate (20 mm×10 mm) with a thickness of 100 μm, a Si semiconductor element (1 mm×1 mm) was placed thereon, and the joining material was heated at 200° C. for 10 minutes to form a joining structure including a joining part with a content ratio in Table 1. When this joining structure was measured with a differential scanning calorimeter, the endothermic peak was positioned at 279.7° C. This means that the joining part has heat resistance with a melting temperature of more than or equal to 400° C. The result of measuring the joining strength of the Si semiconductor element with a bond tester was 8.4 MPa, and this numerical value showed a sufficient joining strength.

The median size of the first metal phase at the joining part was 3.0 μm.

### Examples 2 to 7 and Comparative Examples 1 to 5

In the same manner as in Example 1, joining structures including joining parts with content ratios shown in Table 1 were obtained, and the melting temperature and the joining strength thereof were measured.

As can be seen from Table 1, when the Bi content ratio of the joining part is more than or equal to 26.7 mass %, the joining strength exceeds 6 MPa, and sufficient joining strength can be obtained. When the Bi content ratio of the joining part exceeds 36.7 mass %, the melting temperature decreases to less than 260° C., and thus it cannot be said that the heat resistance is necessarily sufficient. From these results, the Bi content of the joining part necessary for obtaining sufficient joining strength is more than or equal to 26.7 mass %, and the Bi content of the joining part is preferably less than or equal to 36.7 mass % to obtain a melting temperature of more than or equal to 260° C.

### Examples 8 to 14 and Comparative Examples 6 to 9

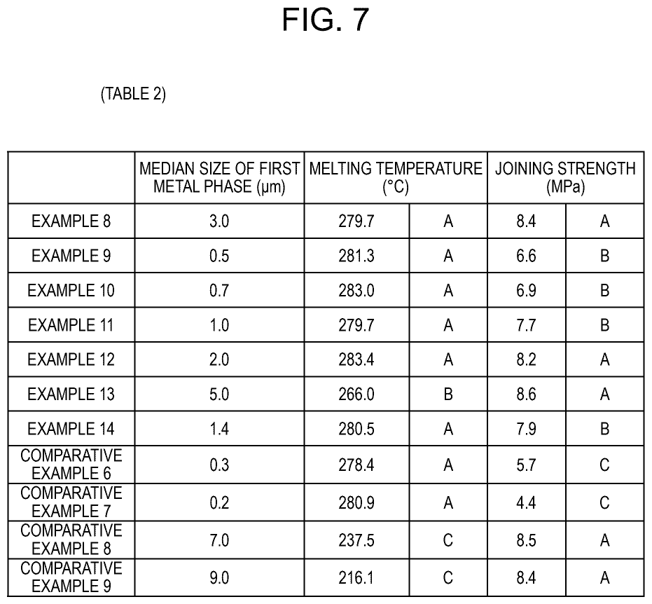

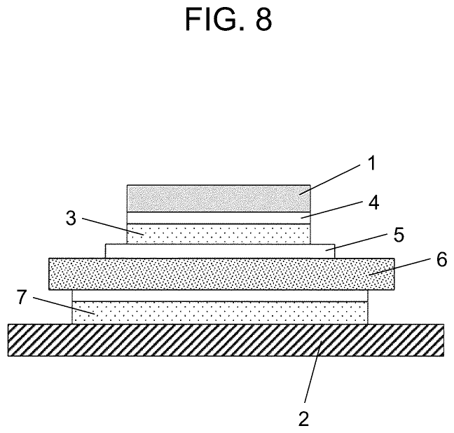

In the same manner as in Examples and Comparative Examples described above, an experiment was conducted in which joining parts in which the median size of the first metal phase of the joining part was variously changed were formed in the same manner as described above, and the melting temperature and the joining strength thereof were measured. The results are shown in Table 2 of FIG. 7. The distinction between Examples and Comparative Examples in the table and their evaluations are the same as described above. Table 2 in FIG. 7 also shows the results of Example 1 as Example 8 corresponding to Example 1.

As can be seen from Table 2, when the median size of the first metal phase of the joining part is more than or equal to 0.5 μm, the joining strength exceeds 6 MPa, and sufficient joining strength can be obtained. When the median size of the first metal phase exceeds 5.0 μm, the melting temperature decreases to less than 260° C., and thus it cannot be said that the heat resistance is necessarily sufficient. From these results, the median size of the first metal phase necessary for obtaining sufficient joining strength is more than or equal to 0.5 μm, and to obtain a melting temperature of more than or equal to 260° C., the median size of the first metal phase of the joining part is preferably less than or equal to 5 μm.

From these results, when the first metal particles and the second metal particles are mixed to form a joining part in which the Bi content ratio of the joining part is 26.7 mass % to 36.7 mass %, the joining part forms a first metal phase and a second metal phase. The first metal phase contains Bi derived from the first metal particles as a main component. The second metal phase is derived from CuSnIn that is an intermetallic compound derived from the first metal particles and the second metal particles, and the second metal phase contains the intermetallic compound as a main component. The joining part has a structure in which the first metal phase is surrounded by the second metal phase. The second metal phase is a joining structure having a three-dimensional network structure and having the first metal phase therein, in which an external electrode and an insulating circuit board electrode are joined. As a result, the joining part has a heat resistance with which the network structure is maintained without melting even when the joining part is heated to more than or equal to 300° C., for example, a high temperature close to 400° C.

The present disclosure includes an appropriate combination of any exemplary embodiment and/or example among the various above-described exemplary embodiments and/or examples, and effects of each of the exemplary embodiments and/or examples can be achieved.

### INDUSTRIAL APPLICABILITY

When the joining structure material according to the present disclosure is used, the first metal particles are melted at a temperature of less than or equal to 150° C. at the time of soldering with a heating device, and thus soldering can be performed at a low temperature. As a result, in the joining method of joining an object using such a joining material, it is possible to reduce the energy consumption in the process of mounting a semiconductor element. Further, in the formed joining part, the second metal of the second metal particles diffuses into a liquid phase generated by melting of the first metal particles to form an intermetallic compound with Sn, In, or the like, and the intermetallic compound has a network structure. Thus, the heat resistance of the joining part is increased, and it is possible to suppress a decrease in reliability of the joining part even when the joining material is used for joining a semiconductor element having a large amount of heat generation such as a GaN semiconductor element or a SiC semiconductor element.

### REFERENCE MARKS IN THE DRAWINGS

1 semiconductor element
2 base plate
3 first joining part
4 external electrode
5 insulating circuit board electrode
6 insulating substrate
7 second joining part
100 joining structure
101 semiconductor element
102 external electrode
103 joining part
104 insulating substrate
105 insulating circuit board electrode
106 first metal phase
107 second metal phase
108 first metal particle
109 second metal particle
110 composite metal particle
111 particle mixture
112 binder
113 joining material
114 melted first metal particle
115 intermetallic compound

1. A joining structure comprising a joining part that joins two objects, wherein
the joining part includes:
a first metal phase containing Bi as a main component, the first metal phase having a granular shape with an average size of 0.5 μm to 5 μm; and
a second metal phase containing Cu as a main component and containing Sn and In,
the first metal phase is dispersed in the second metal phase, and
the joining part has a metal composition proportion of Sn: 9.4 mass % to 19.4 mass %, Bi: 26.7 mass % to 36.7 mass %, In: 6.5 mass % to 16.5 mass %, and Cu: a balance.

2. The joining structure according to claim 1, wherein the second metal phase contains Cu₃(Sn, In).

3. The joining structure according to claim 1, wherein
at least one of the two objects is Cu, and
at least one of Cu₆Sn₅ and Cu₃Sn is contained between the at least one of the two objects and the second metal phase.

4. A joining material for forming a joining part that joins two objects, the joining material comprising:
a composite metal particle including a first metal particle as a core and a second metal particle covering a surface of the core, the first metal particle containing a first metal containing a Sn—Bi—In-based alloy as a main component, the second metal particle containing a second metal made of a simple metal of Cu, Ag, or Ni that reacts with Sn or In to generate an intermetallic compound or an alloy between these simple metals;
a first metal particle that is present separately from the composite metal particle, the first metal particle containing a first metal containing a Sn—Bi—In-based alloy as a main component; and
a binder covering a whole,
wherein the whole has a metal composition proportion of Sn: 9.4 mass % to 19.4 mass %, Bi: 26.7 mass % to 36.7 mass %, In: 6.5 mass % to 16.5 mass %, and the second metal: a balance.
